(19) United States
(12) Patent Application Publication
(10) Pub. No.: US 2022/0120802 A1
(43) Pub. Date: Apr. 21, 2022

(54) METHOD FOR MONITORING A SWITCH OF A RAILWAY TRACK INSTALLATION

(71) Applicant: Siemens Mobility GmbH, Muenchen (DE)

(72) Inventor: Katja Worm, Berlin (DE)

(21) Appl. No.: 17/434,508

(22) PCT Filed: Jan. 27, 2020
(86) PCT No.: PCT/EP2020/051873

§ 371 Date: Aug. 27, 2021

(30) Foreign Application Priority Data
Feb. 27, 2019 (DE) 102019202631.1

(51) Int. Cl. G01R 31/00; B61L 27/53; G06N 20/10

(52) U.S. Cl. CPC G01R 31/008; G06N 20/10; B61L 27/53

(57) ABSTRACT

In a railway track installation, a method for determining a classification model for a railroad switch of the railway track installation enables a fault in the switch to be identified using values measured during a switch operation. A reference operation data set is determined for each of a plurality of switch operations. Each reference operation data set relates to at least two physical variables measured during the respective switch operation. The classification model is determined on the basis of the plurality of reference operation data sets.

The invention relates to methods and devices that allow particularly reliable monitoring of switches of a railway track installation or provide a basis therefor, in particular in the form of a classification model.

Korean patent document KR 101823067 B1 discloses a method for monitoring a switch of a railway track installation. In the previously known method, the current consumption of a a switch drive of the a switch is acquired for a switch that are considered to be functional or considered to be fault-free, and corresponding reference values are stored. If, during subsequent operation of the switch, it is established that current measured values do not correlate with reference measured values, then a corresponding fault signal is generated and indicates a fault with the switch.

Document US 2018 0154 913 A1 describes a computer-implemented method for notifying a user about the presence of a fault in an electromechanical system in a railway track infrastructure. The method comprises receiving electrical usage data that specify the value of an electrical usage parameter that is associated with the electromechanical system and receiving temperature data that indicate the current temperature of the electromechanical system. It is furthermore determined, based on a predetermined relationship between the electrical usage parameter and the temperature, whether the value of the electrical usage parameter indicates a fault in the electromechanical system. If this is the case, a warning takes place in order to indicate the presence of the fault.

The invention is based inter alia on the object of specifying a method for determining a classification model that makes it possible to monitor a switch of a railway track installation in a particularly reliable manner.

In order to achieve this object, the invention makes provision for a method having the features as claimed in patent claim 1. Advantageous refinements of this method are specified in the dependent claims.

According to the invention, there is accordingly provision to determine a respective reference switch data record for a multiplicity of switching operations, which reference switch data record relates in each case to at least two physical measured variables measured during the respective switching operation, and to determine a classification model on the basis of this multiplicity of reference switch data records.

One key advantage of the method according to the invention is that—unlike the previously known method—switches are monitored not on the basis of an individual physical measured variable (this is the current there), but rather on the basis of at least two or more measured variables, as a result of which an expanded classification model is formed and particularly reliable fault identification is made possible.

It is considered to be advantageous for the classification model to be determined using or on the basis solely of reference switch data records whose associated switching operations are considered to be fault-free.

For each switching operation of the switch, an at least two-dimensional feature vector associated with a predefined vector space is preferably created as reference switch data record, the at least two vector components of which feature vector relate to the at least two physical measured variables measured during the switch switch.

The feature vectors preferably define a section of space within the vector space that forms the classification model and allows a test, in order to form the fault signal, as to whether or not feature vectors generated following the completion of the classification model for subsequent switching operations lie outside this section of space beyond a predefined extent.

It is advantageous for the classification model to be determined at least also on the basis of reference switch data records that relate to a predefined number of switching operations following initial installation of the switch or to a predefined time interval following the initial installation of the switch. Such reference switch data records created following the initial installation specifically most likely define functional switches and form positive examples of functional switches.

As an alternative or in addition, there may advantageously be provision for the classification model to be determined at least also on the basis of reference switch data records that relate to a predefined number of switching operations following maintenance of the switch or to a predefined time interval following the maintenance of the switch. Such reference switch data records created following maintenance specifically most likely define functional switches and form positive examples of functional switches.

As an alternative or in addition, there may advantageously be provision for the classification model to be determined at least also on the basis of reference switch data records that relate to a predefined number of switching operations following repair of the switch or to a predefined time interval following the repair of the switch. Such reference switch data records created following repair specifically most likely define functional switches and form positive examples of functional switches.

It is advantageous for a first classification model to be determined on the basis of reference switch data records that relate to a predefined number of switching operations following the initial installation of the switch or to a predefined time interval following the initial installation of the switch. The first classification model may thereafter advantageously be modified by forming a second classification model on the basis of reference switch data records that relate to a predefined number of switching operations following first-time maintenance or first-time repair of the switch or to a predefined time interval following first-time maintenance or first-time repair of the switch.

It is particularly advantageous, following each repair or maintenance, for an existing classification model to be modified by forming an updated classification model on the basis of reference switch data records that relate to a predefined number of switching operations following the respective maintenance or repair of the switch or to a predefined time interval following the respective maintenance or repair of the switch.

The reference switch data records in each case at least also preferably indicate the switching duration of the switch as one of the measured physical measured variables. The switching duration of the switch is a particularly suitable measured variable for identifying faults.

The classification model is particularly preferably determined using or on the basis of a one class support vector machine method.

When forming the second and/or updated classification model, a warning signal may advantageously be generated for reference switch data records that lie outside a switch state range defined by the in each case previous classification model as a permissible switch state. The measurement and/or the switch function may be checked when warning signals are present.

The invention furthermore relates to a method for establishing a fault with switches within a railway track installation. With regard to such a method, the invention makes provision that a switch data record is created during or following the completion of a switching operation of the switch, this switch data record relating to at least two physical measured variables measured during the switch switch, the switch data record is compared with a classification model that has been determined in accordance with a method—as described above—for the same at least two measured variables and, in the event that the switch data record lies outside a switch state range defined by the classification model as a permissible switch state, a fault signal indicating faulty behavior of the switch is generated. This last-mentioned method according to the invention is thus based on using a classification model that is based on at least two physical measured variables and is thus able to be performed in a particularly reliable manner; in this regard, reference is made to the above explanations in connection with the method for determining a classification model, these applying accordingly here.

The invention furthermore relates to a device for determining a classification model for a switch of a railway track installation that makes it possible to establish the fault with the switch. With regard to such a device, the invention makes provision for the device to be designed to determine the classification model on the basis of a multiplicity of reference switch data records that each relate to at least two physical measured variables measured during the respective switching operation. With regard to the advantages of the device according to the invention, reference is made to the above explanations in connection with the method according to the invention for determining a classification model, since these explanations apply accordingly here.

The invention furthermore relates to a device for establishing a fault with a switch of a railway track installation. According to the invention, provision is made in this regard for the device to be designed, during or following the completion of a switching operation of the switch, to create a switch data record that relates to at least two physical measured variables measured during the switch switch, to compare the switch data record with a classification model that was determined on the basis of a multiplicity of reference switch data records and, in the event that the switch data record lies outside a switch state range defined by the classification model as a permissible switch state, to generate a fault signal indicating faulty behavior of the switch. With regard to the advantages of the last-mentioned device according to the invention, reference is made to the above explanations in connection with the method according to the invention for identifying a fault with a switch of a railway track installation, these applying accordingly here.

It is advantageous for said devices to have a computing device and a memory storing a computer program product that, when executed by the computing device, prompts same to perform one or all of the methods described above.

The invention furthermore relates to a computer program product that is suitable, when executed by a computing device, for prompting same to perform one or all of the methods described above.

The invention is explained in more detail below with reference to exemplary embodiments in which, in each case by way of example

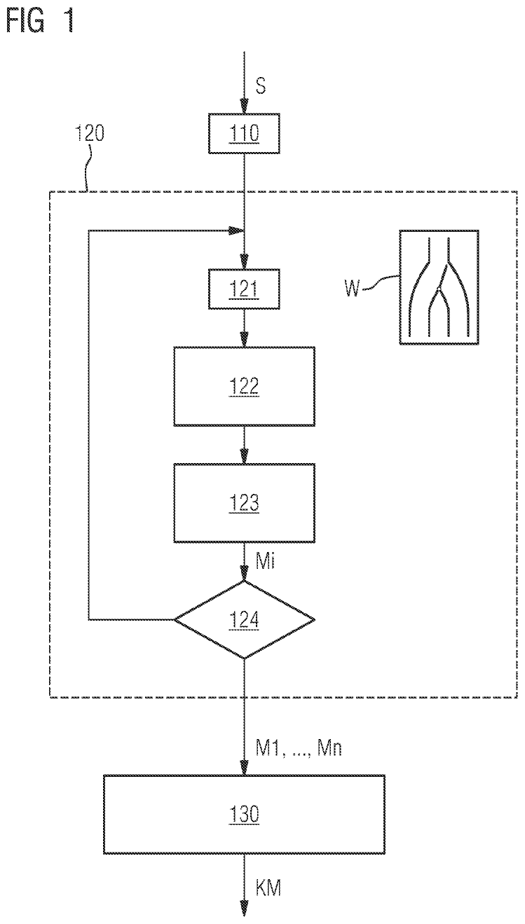

FIG. 1 shows a flowchart of a first exemplary embodiment of a method according to the invention,

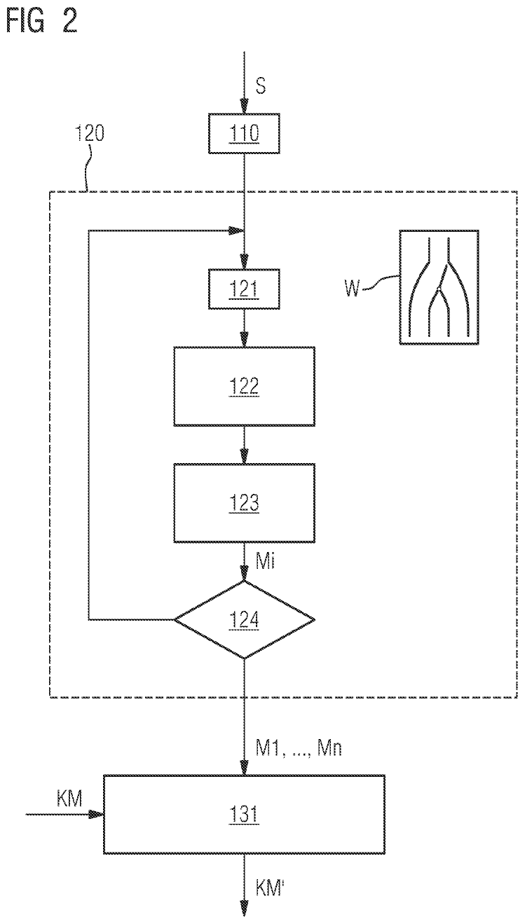

FIG. 2 shows a flowchart of a second exemplary embodiment of a method according to the invention,

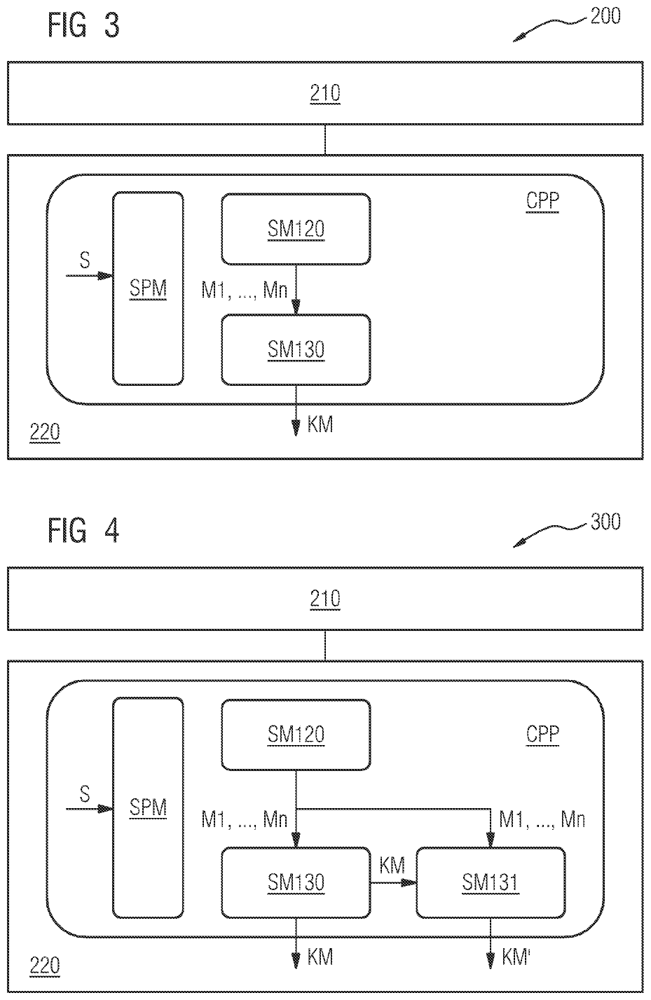

FIG. 3 shows a block diagram of an exemplary embodiment of a device according to the invention for determining a classification model,

FIG. 4 shows a block diagram of a second exemplary embodiment of a device for determining a classification model,

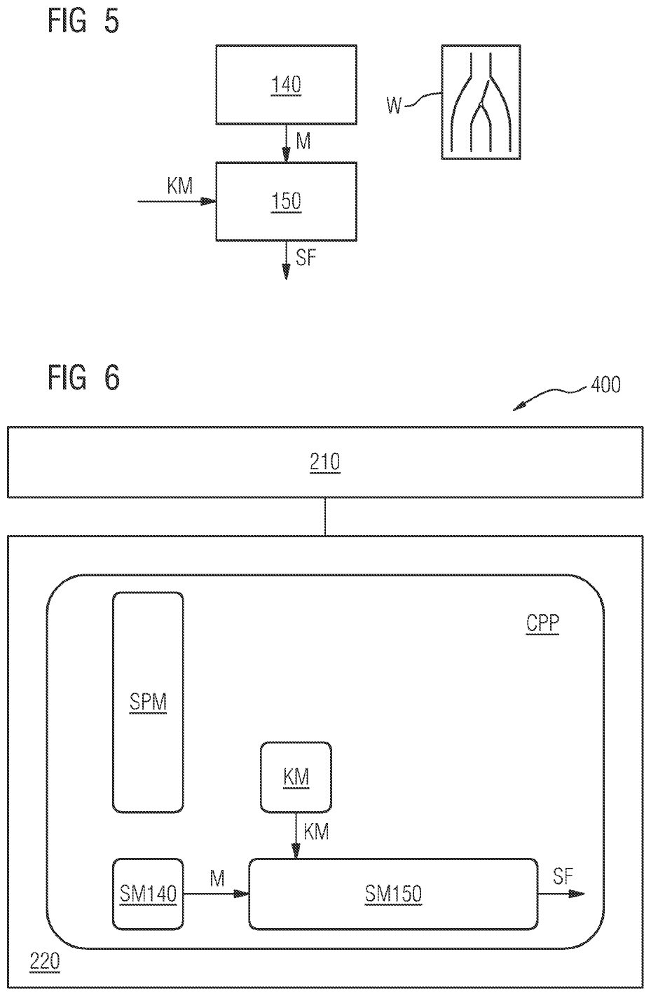

FIG. 5 shows a flowchart of an exemplary embodiment of a method according to the invention for monitoring a switch of a railway track installation,

FIG. 6 shows a block diagram of a first exemplary embodiment of a device for establishing a fault with a switch of a railway track installation, and

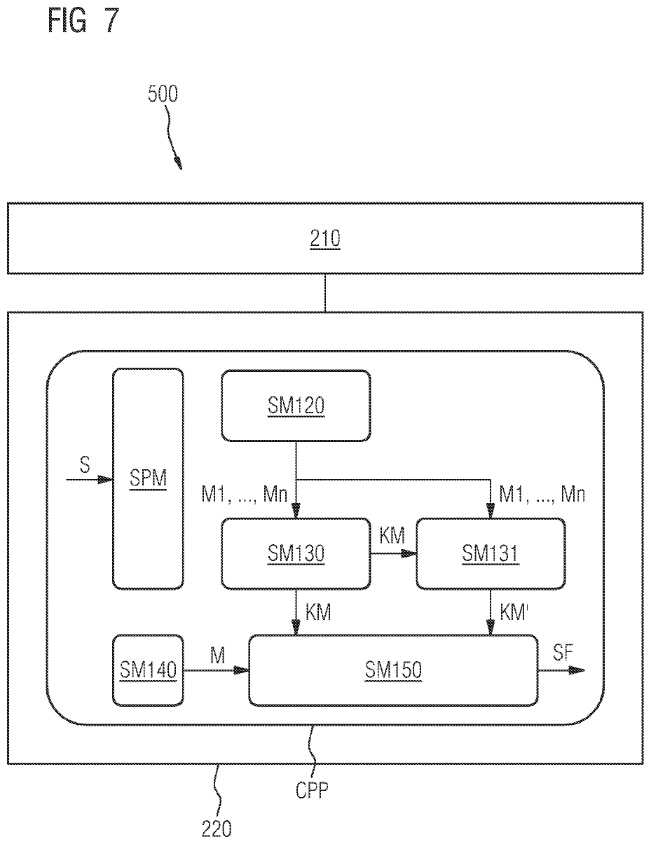

FIG. 7 shows a block diagram of a second exemplary embodiment of a device for establishing a fault with a switch of a railway track installation.

In the figures, the same reference signs are always used for identical or comparable components for the sake of clarity.

FIG. 1 shows a flowchart of an exemplary embodiment of a method for determining a classification model KM that makes it possible to establish a fault with a switch W of a railway track installation on the basis of measured values measured during a switching operation.

In the course of a method step 110, it is monitored whether a start signal S for starting the method or for starting the determination of the classification model KM is present. If this is the case, then a subsequent acquisition procedure 120 for acquiring reference switch data records is started.

In the course of the acquisition procedure 120, a monitoring step 121 for identifying and monitoring the respectively next switching operation is first of all started. If the beginning of a new switching operation is identified in method step 121, then, in a subsequent method step 122, in each case at least two physical measured variables are acquired through measurement for the respective switching operation. The physical measured variables may be for example the current consumption or the maximum current of an electric drive motor of the respective switch W or the switch switching time of the switch W. As an alternative or in addition, further physical measured variables may also be taken into consideration, such as for example the maximum electric power consumption and/or any phase offset between current and voltage at the drive motor of the switch W.

In a subsequent method step 123, a respective reference switch data record is determined for the respective switching operation, this reference switch data record relating to the at least two physical measured variables. It is assumed by way of example below that a two-dimensional or multi-dimensional feature vector is created as reference switch data record, the vector components of which feature vector relate to the physical measured variables measured during the respective switching operation.

FIG. 1 denotes the feature vector formed in method step 123 using the reference sign Mi, with the index i denoting the ith switching operation following the presence of the start signal S. The feature vector M1 would thus denote the first feature vector following the presence of the start signal S, and the feature vector Mn would denote the nth feature vector following the presence of the start signal S.

If for example two physical measured variables, such as current consumption and switching operationing time, are measured, then the feature vector at the ith switching operation following the onset of the start signal S would be a two-dimensional vector, reading for example as follows:

Mi=(I, T)

with I denoting the current during the ith switching operation and T denoting the switching duration during the ith switching operation.

In a subsequent method step 124, it is checked whether, following the onset of the start signal S, enough switching operations have already been acquired or a predefined minimum number of switches has been reached. By way of example, in method step 124, it may be checked whether a number n=10 of switching operations has been acquired. If this is the case, then, in method step 124, the measured feature vectors M1, . . . , M10 are output. If the number n=10 of switching operations has not yet been reached, method step 121 continues to further monitor switching operations until the predefined number of switching operations has been reached.

Instead of a predefined number of switching operations, it may also be checked in method step 124 whether a predefined time interval T following the onset of the start signal S has elapsed. If this is the case, method step 130 is continued, and if not the recording of the in each case next feature vector is continued in method step 121.

After the completion of the acquisition procedure 120, the classification model KM is generated in subsequent method step 130 on the basis of the generated feature vectors M1, . . . , Mn. It is considered to be particularly advantageous for the classification model KM to be determined using or based on a one class support vector machine method. In this regard, reference is made here to the known literature describing the generation of classification models on the basis of one class support vector machine methods in detail, for example:
“Support Vector Method for Novelty Detection”, Bernhard Schölkopf, Robert Williamson, Alex Smola, John-Shawe Taylor, John Platt, Advances in Neural Information Processing Systems 12, June 2000, Pages 582-588, MIT Press, and
“Estimating the Support of a High-Dimensional Distribution”, Bernhard Schölkopf, John C. Platt, John C. Shawe-Taylor, Alex J. Smola, Robert C. Williamson, Neural Computation archive, Volume 13 Issue 7, July 2001, Pages 1443-1471, MIT Press Cambridge, Mass., USA

In summary, the classification model KM in the method according to FIG. 1 is created on the basis of feature vectors or reference switch data records that relate to a predefined number of switching operations following the presence of the start signal S or to switching operations that have taken place within a predefined time interval following the presence of the start signal S.

If the start signal S is generated following reinstallation of the switch W or following maintenance or repair of the switch W, then it may most likely be assumed that the feature vectors M or the corresponding reference switch data records characterize functional or fault-free switches W and thus make it possible to form a classification model that is “trained” to identify fault-free switching operations. The training in the method according to FIG. 1 thus takes place solely on the basis of positive examples that relate to fault-free switching operations; negative examples of faulty switches are not necessary to train the classification model KM.

In the exemplary embodiment according to FIG. 1, the classification model KM is generated on the basis of a one class support vector machine method; as an alternative, other methods may of course be used, by way of which it is possible to create a classification model KM based solely on positive examples, that is to say based solely on reference switch data records considered “to be fault-free”. In this connection, mention may be made for example of methods that are described in the following literature citations:
“A review of Novelty Detection”, Marco A. F. Pimentel, David A. Clifton, Lei Clifton, Lionel Tarassenko, Signal Processing, Volume 99, June 2014, pages 215-249, Elsevier,
“A survey of Recent Trends in One Class Classification”, Shehroz S. Khan, Michael G. Madden, Artificial Intelligence and Cognitive Science, pages 188-197, 2009, Springer, and
“Review of Novelty Detection Methods”, Dubravko Miljkovic, The 33rd International Convention MIPRO, May 2010, IEEE.

FIG. 2 shows a method for determining a classification model KM′ that is created on the basis of a pre-existing classification model KM by updating or modifying this existing classification model KM:

Following the presence of a start signal S and the subsequent acquisition of reference switch data records in the acquisition procedure 120 (in this regard, see the explanations in connection with FIG. 1), the pre-existing classification model KM is modified on the basis of the newly generated feature vectors M1, . . . , Mn in a modification method 131. Such a modification is particularly easily possible by integrating the newly generated feature vectors M1, . . . , Mn into the existing classification model KM, as a result of which the modified or new classification model KM′ is generated.

It is also possible to apply the feature vectors that were used to form the existing classification model KM, together with the newly generated feature vectors M1, . . . , Mn, to form the modified or new classification model KM′.

For the rest, the above explanations in connection with FIG. 1 apply accordingly to the method according to FIG. 2.

FIG. 3 shows an exemplary embodiment of a device 200 for determining a classification model KM. The device 200 comprises a computing device 210 and a memory 220.

The memory 220 stores a computer program product CPP that contains a control program module SPM, a software module SM120 and a software module SM130 for generating a classification model KM. The software modules SM120 and SM130 are controlled by the control program module SPM.

The software module SM120 executes the acquisition procedure 120 explained above in connection with FIGS. 1 and 2, that is to say method steps 121 to 124 of generating reference switch data records or feature vectors M as soon as the control program module SPM receives a corresponding start signal S.

The software module SM130, in a manner controlled by the control program module SPM, using the reference switch data records of the software module SM120 and the corresponding feature vectors M, forms the classification model KM in accordance with method step 130, as has been explained above in connection with FIGS. 1 and 2.

FIG. 4 shows an exemplary embodiment of a device 300 that is suitable not only for generating a classification model KM, but also for modifying a pre-existing classification model KM and generating a modified classification model KM′. To this end, the device 300 has an additional software module SM131 that is able, on the basis of an already previously generated classification model KM and on the basis of newly created feature vectors M, to form an updated or modified classification model KM′, as has been explained above in connection with the exemplary embodiment according to FIG. 2 and the corresponding modification method 131.

FIG. 5 shows a flowchart of an exemplary embodiment of a method for establishing a fault with a switch W of a railway track installation. In the course of a method step 140, each switching operation of the switch W is monitored and a corresponding switch data record, preferably in the form of a feature vector M, is generated. In an evaluation step 150, it is checked whether the respective switch data record characterizes a fault-free switching operation in accordance with a predefined classification model KM. If it is established that the switch data record lies outside a switch state range defined by the classification model KM as a permissible switch state, then a fault signal SF is generated.

The classification model KM may for example have been generated in the course of the method according to FIG. 1 or in the course of the method according to FIG. 2.

FIG. 6 shows an exemplary embodiment of a device 400 for establishing a fault with a switch W of a railway track installation. The device 400 comprises a computing device 210 and a memory 220. The memory 220 stores a computer program product CPP that has a control program module SPM, a software module SM140, a software module SM150 and a classification model KM.

If the control program module SPM establishes that a new switching operation takes place, then the software module SM140 generates a switch data record or feature vector M that characterizes the respective switching operation on the basis of at least two physical measured variables.

The software module SM150 then checks whether the acquired switch data record or the feature vector M lies outside a switch state range defined by the classification model KM as an additional switch state. If this is the case, the fault signal SF is generated.

The software module SM140 preferably executes method step 140 as has been explained in connection with FIG. 5. The software module SM150 preferably executes evaluation step 150 as has been explained in connection with FIG. 5.

FIG. 7 shows a further exemplary embodiment of a device 500 for establishing a fault with a switch W of a railway track installation. The device according to FIG. 7, in addition to the software modules SM140 and SM150, contains the software modules SM120, SM130 and SM131, which are suitable for generating a classification model KM and for modifying or updating an existing classification model KM so as to form an updated classification model KM′. With regard to the software modules SM120, SM130 and SM131, reference is made to the above explanations in connection with FIGS. 3 and 4, these applying accordingly here.

In the exemplary embodiment according to FIG. 7, the device 500 may thus not only identify a fault and possibly generate a fault signal SF on the basis of switch data records or newly measured feature vectors, but rather furthermore also generate classification models KM or form modified classification models KM′.

The control program module SPM is preferably designed such that, in the presence of a start signal S, it triggers in each case the formation of a classification model KM using the software modules SM120 and SM130, provided that no classification model KM has yet been created. It is preferably necessary to regenerate a classification model following initial commissioning of the switch W.

If a previously generated classification model KM is already present, then the control program module SPM, preferably the software module SM131, is activated when a start signal S is present in order to update the existing classification model KM by forming an updated classification model KM′. The respectively present classification model is preferably updated in each case following each maintenance or repair.

A first classification model is preferably formed and updated classification models are preferably formed in each case on the basis of a predefined number of switching operations following the onset of the start signal S or within a predefined time interval following the onset of a start signal S. A start signal S is preferably generated following reinstallation of the switch W and following maintenance and/or repair of the switch W and entered into the control program module SPM.

Although the invention has been described and illustrated in more detail by preferred exemplary embodiments, the invention is not restricted by the disclosed examples and other variations may be derived therefrom by a person skilled in the art without departing from the scope of protection of the invention.

### List of Reference Signs

110 method step
120 acquisition procedure
121 monitoring step
122 method step
123 method step
124 method step
130 method step
131 modification method
140 method step
150 evaluation step
200 device
210 computing device
220 memory
300 device
400 device
500 device
CPP computer program product
KM classification model
KM′ classification model
M1 feature vector
M feature vector
Mi feature vector
Mn feature vector
S start signal
SF fault signal
SM120 software module
SM130 software module
SM131 software module
SM140 software module
SM150 software module
SPM control program module
W switch

1-14. (canceled)

15. A method of determining a classification model for a switch of a railway track installation, for enabling a fault of the switch to be established based on measured values measured during a switching operation, the method comprising:
determining a respective reference switch data record for a multiplicity of switch operations, the reference switch data record in each case relating to at least two physical measured variables measured during a respective switching operation; and
determining the classification model based on the multiplicity of reference switch data records;
for each switching operation of the switch, creating the reference switch data record with a multi-dimensional feature vector associated with a predefined vector space, the feature vector having at least two vector components relating to the at least two physical measured variables measured during the switching operation; and
the feature vectors defining a section of space within the vector space, the section of space forming the classification model and enabling a test, in order to form a fault signal, as to whether or not feature vectors generated following a completion of the classification model for subsequent switch operations lie outside the section of space beyond a predefined extent.

16. The method according to claim 15, which comprises determining the classification model using reference switch data records whose associated switching operations are considered to be fault-free.

17. The method according to claim 15, which comprises determining the classification model solely on a basis of reference switch data records whose associated switching operations are considered to be fault-free.

18. The method according to claim 15, which comprises determining the classification model at least also on a basis of reference switch data records that relate to a predefined number of switching operations following an initial installation of the switch or to a predefined time interval following the initial installation of the switch.

19. The method according to claim 15, which comprises determining the classification model at least also on a basis of reference switch data records that relate to a predefined number of switching operations following a maintenance of the switch or to a predefined time interval following the maintenance of the switch.

20. The method according to claim 15, which comprises determining the classification model at least also on a basis of reference switch data records that relate to a predefined number of switching operations following a repair of the switch or to a predefined time interval following the repair of the switch.

21. The method according to claim 15, which comprises:
determining a first classification model based on reference switch data records that relate to a predefined number of switching operations following an initial installation of the switch or to a predefined time interval following the initial installation of the switch; and
modifying the first classification model to form a second classification model based on reference switch data records that relate to a predefined number of switching operations following a first-time maintenance or a first-time repair of the switch or to a predefined time interval following the first-time maintenance or the first-time repair of the switch.

22. The method according to claim 15, which comprises following each repair or maintenance of the switch, modifying an existing classification model to form an updated classification model based of reference switch data records relating to a predefined number of switching operations following a respective maintenance or repair of the switch or to a predefined time interval following the respective maintenance or repair of the switch.

23. The method according to claim 15, wherein each of the reference switch data records also specify a respective switching duration of the switch as one of the measured physical measured variables.

24. The method according to claim 15, which comprises determining the classification model using a one class support vector machine process.

25. The method according to claim 15, which comprises determining the classification model based on a one class support vector machine process.

26. A method for establishing a fault of a switch of a railway track installation, the method comprising:
during or following a completion of a switching operation of the switch, creating a switch data record that relates to at least two physical measured variables measured during the switching operation;
comparing the switch data record with a classification model determined with the method according to claim 15 for the at least two physical measured variables; and
if the switch data record lies outside a switch state range defined by the classification model as being a permissible switch state, generating a fault signal indicating a faulty behavior of the switch.

27. A device for determining a classification model for a switch of a railway track installation, wherein the classification model enables establishing a fault of the switch, the device comprising a processor and a memory, said processor being configured to:
determine the classification model based on a multiplicity of reference switch data records each relating to at least two physical measured variables measured during a respective switching operation of the switch; and
create a reference switch data record for each switching operation of the switch, the reference switch data record having a multi-dimensional feature vector associated with a predefined vector space, the feature vector having at least two vector components relating to the at least two physical measured variables measured during the switching operation;
wherein the feature vectors define a section of space within the vector space, and the section of space forms the classification model and enables a test, in order to form a fault signal, as to whether or not feature vectors generated following the completion of the classification model for subsequent switch operations lie outside the section of space beyond a predefined extent.

28. The device according to claim 27, wherein said processor forms part of a computing device that has a memory connected thereto, said memory storing a computer program product which, when executed by said computing device, causes the computing device to perform the method according to clam 15.

29. A device for establishing a fault of a switch of a railway track installation, wherein the device is configured, during or after a completion of a switching operation of the switch, to create a switch data record that relates to at least two physical measured variables measured during the switching operation, to compare the switch data record with a classification model that was determined on a basis of a multiplicity of reference switch data records and, if the switch data record lies outside a switch state range defined by the classification model as a permissible switch state, to create a fault signal indicating faulty behavior of the switch.

30. The device according to claim 29, comprising a computing device and a memory storing a computer program product which, when executed by said computing device, prompts said computing device to perform the method according to claim 15.

31. A computer program product, comprising computer-executable code stored in non-transitory form and configured, when executed by a computing device, to perform the method according to claim 15.
